(19) United States
(12) Patent Application Publication
(10) Pub. No.: US 2020/0203863 A1
(43) Pub. Date: Jun. 25, 2020

(54) CIRCUIT BOARD ASSEMBLY

(71) Applicant: CANON KABUSHIKI KAISHA, Tokyo (JP)

(72) Inventor: Tatsuya Suzuki, Yokohama-shi (JP)

(21) Appl. No.: 16/701,040

(22) Filed: Dec. 2, 2019

(30) Foreign Application Priority Data
Dec. 19, 2018 (JP) 2018-237432

(51) Int. Cl. H01R 12/53; H05K 1/11; H05K 5/00

(52) U.S. Cl. CPC H01R 12/53; H05K 2201/10356; H05K 5/006; H05K 1/117

(57) ABSTRACT

A circuit board assembly including a cable unit, which includes a first plug to be inserted into a first receptacle provided on a first board and a second plug to be inserted into a second receptacle provided on a second board, wherein the first receptacle is configured so that a force required for pulling out the first plug from the first receptacle in a direction inclined toward a first side of the first receptacle with respect to an insertion direction in which the first plug is inserted into the first receptacle is smaller than a force required for pulling out the first plug from the first receptacle in a direction inclined toward a second side with respect to the insertion direction, and wherein the first receptacle is provided on the first board so that the second side is oriented toward the second board.

### BACKGROUND OF THE INVENTION

### Field of the Invention

The present invention relates to a circuit board assembly, which includes a cable unit configured to electrically connect a first board and a second board to each other.

### Description of the Related Art

Hitherto, connectors and cables which are insertable and removable are used for electrically connecting boards such as control boards, power supply boards, and drive boards (Japanese Patent Application Laid-Open No. 2012-179401). The connector includes a receptacle provided on the board and a plug provided at an end of the cable. The plug is insertable and removable with respect to the receptacle.

The receptacle and the plug form a pair. When the insertion of the plug into the receptacle is not reliable, the electrical connection is not achieved. Therefore, it is important that the insertion be reliably performed. Thus, a connector which gives an operator an operational feeling when the insertion has been reliably performed is required. Moreover, when the number of boards forming the circuit board assembly increases, the number of connectors for connecting the plurality of boards increases. Therefore, reduction in cost for the connectors is important. A connector having a complicated structure causes higher cost due to complication of a die and reduction in yield at the time of mass production, and hence a connector having a simple structure is required. Therefore, a connector which has a simple structure and gives an operational feeling is required.

Moreover, in a circuit board assembly which connects a first board and a second board with a cable unit, a plug provided at one end of the cable unit is inserted into a receptacle provided on the first board. A plug provided at the other end of the cable unit is inserted into a receptacle provided on the second board. For example, when the second board fails, the second board can be replaced by pulling out the plug provided at the other end of the cable unit from the receptacle.

However, at the time of replacing the second board having failed, the connector connecting the first board and the cable unit to each other is unintentionally removed in some cases. For example, in order to replace the second board having failed, an operator first pulls out the plug inserted into the receptacle of the second board having failed. Next, the operator replaces the second board having failed with a new board. Then, the operator inserts the plug provided at the other end of the cable unit into the receptacle of the new board. However, at the time of inserting the plug into the receptacle of the new board, the operator pulls the cable unit in some cases. When the cable unit is pulled, the plug provided at the one end of the cable unit is removed from the receptacle of the first board in some cases.

### SUMMARY OF THE INVENTION

In view of the circumstances described above, the present invention has an object to reduce removal of a plug at the time of work by determining an orientation of a receptacle provided on a board.

According to at least one embodiment of the present invention, there is provided a circuit board assembly including: a first board; a first receptacle provided on the first board; a second board; a second receptacle provided on the second board; and a cable unit which includes a first plug to be inserted into the first receptacle and a second plug to be inserted into the second receptacle to electrically connect the first board and the second board to each other, wherein the first receptacle is configured so that a force required for pulling out the first plug from the first receptacle in a direction inclined toward a first side of the first receptacle with respect to a first insertion direction in which the first plug is inserted into the first receptacle is smaller than a force required for pulling out the first plug from the first receptacle in a direction inclined toward a second side opposite to the first side with respect to the first insertion direction, and wherein the first receptacle is provided on the first board so that the second side of the first receptacle is oriented toward the second board.

Further features of the present invention will become apparent from the following description of exemplary embodiments with reference to the attached drawings.

### BRIEF DESCRIPTION OF THE DRAWINGS

FIG. 1A, FIG. 1B, FIG. 1C, FIG. 1D, and FIG. 1E are views for illustrating a first plug and a first receptacle.

FIG. 2 is a block view for illustrating an example of a circuit board assembly.

FIG. 3A and FIG. 3B are views for illustrating angle dependence of a pull-out force of a first connector.

FIG. 4A and FIG. 4B are side views for illustrating the circuit board assembly.

### DESCRIPTION OF THE EMBODIMENTS

(Circuit Board Assembly)

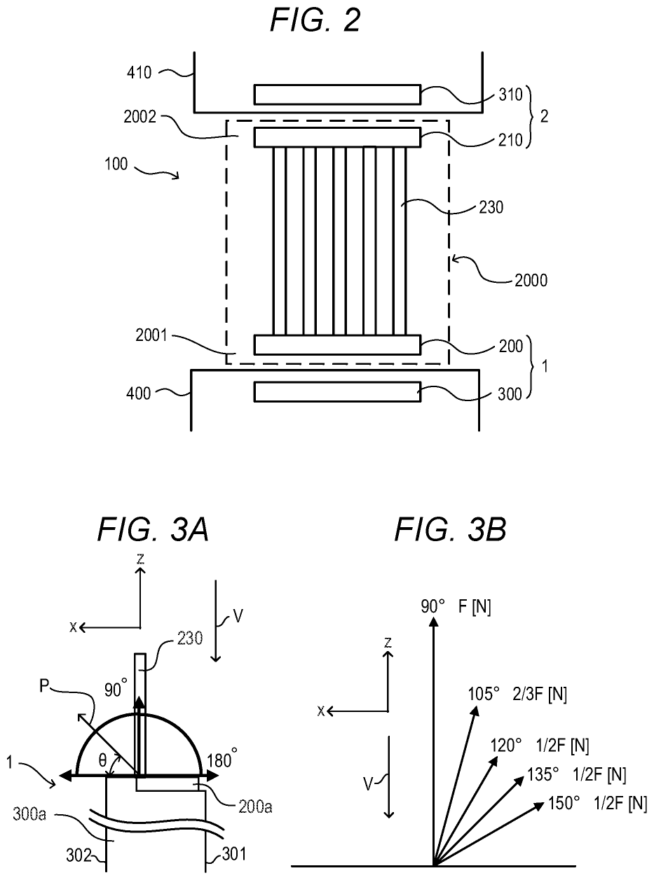

FIG. 2 is a block view for illustrating an example of a circuit board assembly 100. The circuit board assembly 100 includes a first board 400, a second board 410, and a cable unit 2000. The first board 400 and the second board 410 are each an electrical circuit board, on which electrical elements are arranged. The cable unit 2000 is configured to electrically connect the first board 400 and the second board 410 to each other. The first board 400 is electrically connected to one end (hereinafter referred to as “first end”) 2001 of the cable unit 2000 by a first connector 1. The second board 410 is electrically connected to another end (hereinafter referred to as “second end”) 2002 of the cable unit 2000, which is located on a side opposite to the first end 2001, by a second connector 2. The first connector 1 includes a first plug 200 and a first receptacle 300. The first plug 200 is connected to the first receptacle 300 so as to be connectable (insertable and removable). The second connector 2 includes a second plug 210 and a second receptacle 310. The second plug 210 is connected to the second receptacle 310 so as to be connectable (insertable and removable).

The first receptacle 300 is provided on the first board 400. The first receptacle 300 is electrically connected to an electrical circuit on the first board 400. The second receptacle 310 is provided on the second board 410. The second receptacle 310 is electrically connected to an electrical circuit on the second board 410. The cable unit 2000 includes the first plug 200, the second plug 210, and cables 230. The first plug 200 is provided at the first end 2001 of the cable unit 2000. The second plug 210 is provided at the second end 2002 of the cable unit 2000. The first plug 200 and the second plug 210 are electrically connected to each other by the cables 230. The first plug 200 is connected to the first receptacle 300, and the second plug 210 is connected to the second receptacle 310. Thus, the electrical circuit on the first board 400 is electrically connected to the electrical circuit on the second board 410 through the cables 230.

At the time of assembling the circuit board assembly 100, an operator (worker) inserts the first plug 200 into the first receptacle 300 and inserts the second plug 210 into the second receptacle 310. Accordingly, the first board 400 and the second board 410 are electrically connected to each other through the first connector 1, the cable unit 2000, and the second connector 2. In this embodiment, the first connector 1 has the same structure as the second connector 2. However, the first connector 1 and the second connector 2 may have different structures. That is, the first plug 200 and the second plug 210 may have the same structure, or may have different structures. Similarly, the first receptacle 300 and the second receptacle 310 may have the same structure, or may have different structure. The circuit board assembly 100 according to this embodiment includes two boards and one cable unit. However, the circuit board assembly 100 may include three or more boards and a plurality of cable units connecting the boards.

(First Plug and First Receptacle)

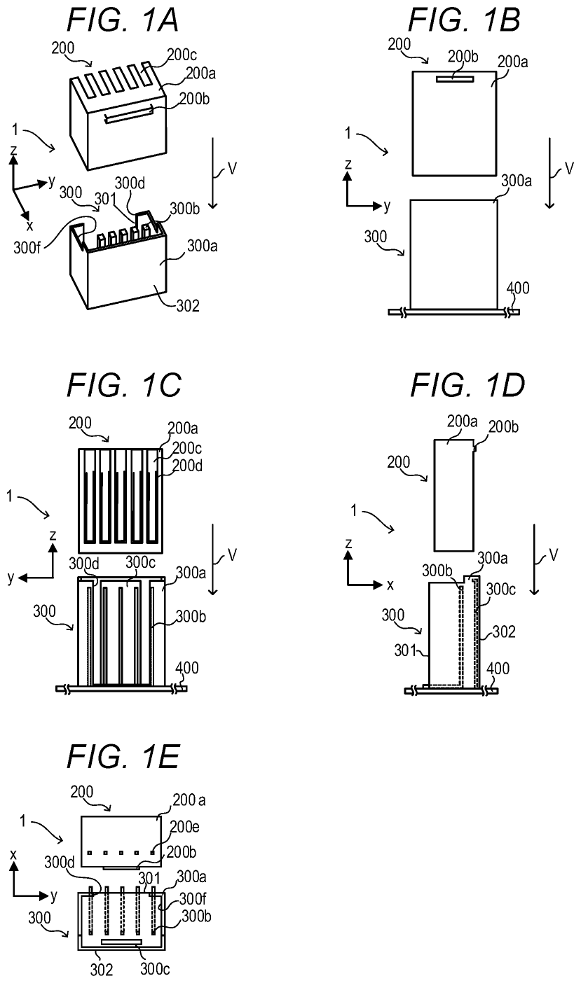

FIG. 1A, FIG. 1B, FIG. 1C, FIG. 1D, and FIG. 1E are views for illustrating the first plug 200 and the first receptacle 300. FIG. 1A is a perspective view for illustrating the first plug 200 and the first receptacle 300 of the first connector 1. FIG. 1B is a front view for illustrating the first plug 200 and the first receptacle 300. FIG. 1C is a back view for illustrating the first plug 200 and the first receptacle 300. FIG. 1D is a side view for illustrating the first plug 200 and the first receptacle 300. FIG. 1E is a bottom view of the first plug 200 and a top view of the first receptacle 300. In FIG. 1A to FIG. 1E, a lateral direction of the first connector 1 is indicated by the arrow “x”, a width direction is indicated by the arrow “y”, and a vertical direction is indicated by the arrow “z”.

The first plug 200 includes a plug main body 200a. The plug main body 200a includes a projection portion (latching portion) 200b, cable storing holes 200c, and introduction holes 200e. In each of the cable storing holes 200c, a cable swaging portion 200d is provided. The cables 230 are brought into press contact with the cable swaging portions 200d provided in the cable storing holes 200c through use of a tool. Claws (not shown) of the cable swaging portions 200d bite into insulating bodies (not shown) on an outer periphery of the cables 230 and are brought into contact with lead wires (not shown) in the cables 230.

The first receptacle 300 includes a receptacle main body 300a. The receptacle main body 300a includes connector terminals 300b, a lock portion (latching portion) 300c, and a cut-out (open portion) 300d. The connector terminals 300b are joined by solder to a land pattern (not shown) formed on the first board 400. The receptacle main body 300a of the first receptacle 300 has an opening 300f which is open in an insertion direction V in which the first plug 200 is inserted into the first receptacle 300. The cut-out 300d communicates to the opening 300f. The insertion direction V is a direction along an opening direction “z” of the opening 300f.

The first plug 200 having the cables 230 brought into abutment thereagainst is inserted into the first receptacle 300 by an operator. At this time, the plug main body 200a of the first plug 200 is inserted into the receptacle main body 300a of the first receptacle 300. When the plug main body 200a is inserted into the receptacle main body 300a by a predetermined amount, the connector terminals 300b provided to the first receptacle 300 are inserted, while being guided, into the introduction holes 200e formed in the first plug 200. As the plug main body 200a is further inserted into the receptacle main body 300a, the projection portion 200b of the first plug 200 climbs over the lock portion 300c of the first receptacle 300, and the connector terminals 300b having been inserted into the introduction holes 200e are brought into contact with the cable swaging portions 200d. As a result, the first plug 200 and the first receptacle 300 are reliably connected to each other. The projection portion 200b climbs over the lock portion 300c when the first plug 200 is reliably inserted into the first receptacle 300, and such an action gives the operator an insertion feeling. That is, when the first plug 200 is connected to the first receptacle 300, and the projection portion 200b of the first plug 200 is latched (locked) to the lock portion 300c of the first receptacle 300, an operational feeling (click feeling) is given to the operator. As described above, the first connector 1 has a simple structure and a characteristic of giving the operational feeling.

Similarly to the first plug 200 and the first receptacle 300, the second plug 210 provided at the second end 2002 of the cable unit 2000 is connected to the second receptacle 310 provided on the second board 410. In such a manner, the first board 400 is electrically connected to the second board 410 through the cable unit 2000.

(Angle Dependence of Pull-Out Force of Connector)

With reference to FIG. 3A and FIG. 3B, an example of an angle dependence of a pull-out force of the first connector 1 is described. FIG. 3A and FIG. 3B are views for illustrating the angle dependence of the pull-out force of the first connector 1. The pull-out force of the first connector 1 is a force required for removing the first plug 200 from the first receptacle 300. The pull-out force of the first connector 1 is dependent on an angle (hereinafter referred to as “pull-out angle”) A of a pull-out direction P of the pull-out force with respect to the direction “x” perpendicular to the opening direction “z” (insertion direction V) of the opening 300f of the first receptacle 300 (FIG. 3A). This is because the projection portion 200b of the first plug 200 is latched by the lock portion 300c of the first receptacle 300. The projection portion 200b is latched by the lock portion 300c, and hence, when the pull-out angle θ falls within a range of from 0° to 90°, the pull-out force required for removing the first plug 200 from the first receptacle 300 is significantly large. The first connector 1 may fail depending on the pull-out angle θ and a magnitude of the pull-out force.

In order to prevent an increase in pull-out force by the latching of the projection portion 200b to the lock portion 300c, the cut-out 300d being an open portion is formed in the first receptacle 300 on a first side 301, which is opposite to a second side 302, on which the lock portion 300c is provided. With the cut-out 300d formed on the first side 301 of the first receptacle 300, the force required for pulling out the first plug 200 from the first receptacle 300 is reduced. Specifically, when the pull-out angle θ is larger than 90°, the pull-out force of the first plug 200 is reduced by the cut-out 300d (FIG. 3B). The pull-out force for pulling out the first plug 200 in a direction inclined toward the first side 301 of the first receptacle 300 with respect to the first insertion direction V is smaller than the pull-out force for pulling out the first plug 200 in a direction inclined toward the second side 302, which is opposite to the first side 301, with respect to the insertion direction V. The direction inclined toward the first side 301 is the pull-out direction P having the pull-out angle θ larger than 90°. The direction inclined toward the second side 302 is the pull-out direction P having the pull-out angle θ smaller than 90°.

A recommended pull-out angle in terms of specifications for an operator of the first connector 1 of the present embodiment falls within a range of from 90° to 105°. As illustrated in FIG. 3B, a force required for an operator to pull out the first plug 200 in the direction of 90° is F(N). A force required for an operator to pull out the first plug 200 in the direction of 105° is ⅔ F(N). Moreover, although it is not a recommended pull-out angle in terms of specifications, a pull-out force is ½ F(N) in the direction falling within a range of from 120° to 150°. A ratio of a force exerted in the horizontal direction on the connector terminals 300b becomes larger in the direction of a pull-out angle equal to or larger than 165°, and hence the pull-out force of the first plug 200 becomes significantly larger. Due to the pull-out angle θ equal to or larger than 165°, and depending on a magnitude of the pull-out force, the first connector 1 may fail. The direction of the pull-out angle θ falling within the range of equal to or larger than 105° and smaller than 165° is not the recommended pull-out angle in terms of specifications, but is assumed to be stress indirectly exerted on the first connector 1 at the time of assembly work or maintenance work for the circuit board assembly 100.

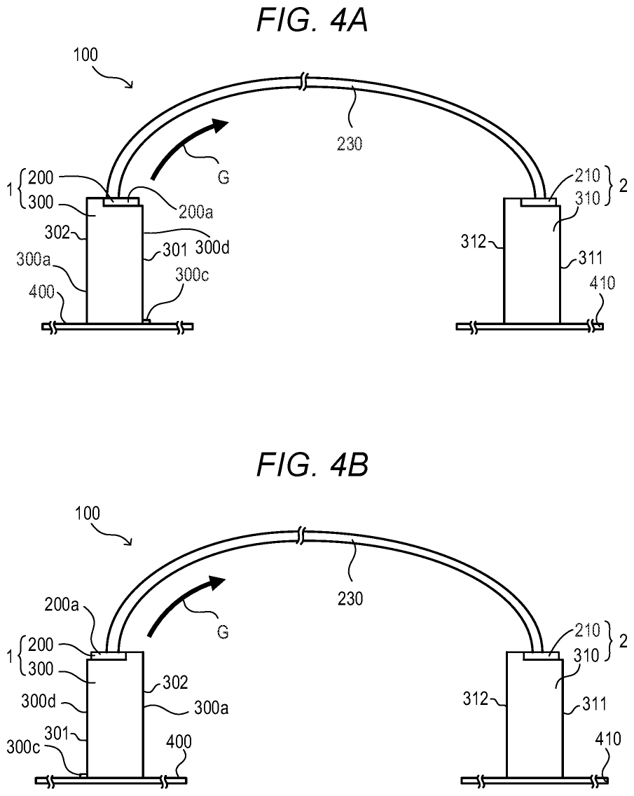

FIG. 4A and FIG. 4B are side views for illustrating the circuit board assembly 100. FIG. 4A is a view for illustrating the circuit board assembly 100 in which the cut-out 300d formed in the receptacle main body 300a on the first board 400 is provided on the side of the second board 410. That is, the first receptacle 300 is provided on the first board 400 so that the second side 302 thereof is oriented in a direction opposite to the second board 410. FIG. 4B is a view for illustrating the circuit board assembly 100 in which the cut-out 300d formed in the receptacle main body 300a on the first board 400 is provided on the side opposite to the second board 410. That is, the first receptacle 300 is provided on the first board 400 so that the second side 302 thereof is oriented in a direction of the second board 410. FIG. 4A and FIG. 4B are explanatory views for illustrating a state in which the second plug 210 is inserted into the second receptacle 310 after an operator performs replacement of the second board 410 of the circuit board assembly 100 at the time of maintenance work.

When an operator inserts the second plug 210 into the second receptacle 310 of the second board 410, stress may be exerted on the first connector 1 of the first board 400 in the direction indicated by the arrow G. As illustrated in FIG. 4A, when the cut-out 300d for allowing an operator to easily pull out the first plug 200 is opened toward the second board 410, the first plug 200 is liable to be removed from the first receptacle 300 due to the stress exerted in the direction indicated by the arrow G.

In contrast, in FIG. 4B, the cut-out 300d of the receptacle main body 300a is located so as to be oriented in a direction opposite to the second board 410. In FIG. 4B, even when the stress is exerted on the first connector 1 of the first board 400 in the direction indicated by the arrow G, the first plug 200 is prevented from being removed from the first receptacle 300. As described above, when the first receptacle 300 is provided on the first board 400 so that the first side 301 thereof on which the cut-out 300d is formed is prevented from being oriented toward the second board 410, the removal of the first plug 200 at the time of the work can be reduced.

In this embodiment, the second connector 2 has the same structure as the first connector 1. A pull-out force for pulling out the second plug 210 in a direction inclined toward a first side 311 of the second receptacle 310 with respect to a second insertion direction is smaller than a pull-out force for pulling out the second plug 210 in a direction inclined toward a second side 312 opposite to the first side 311 with respect to the insertion direction. The second receptacle 310 of the second connector 2 is provided so that the first side 311 thereof on which the cut-out is formed is prevented from being oriented toward the first board 400 having the first connector 1 provided thereon. That is, the second receptacle 310 is provided so that the second side 312 thereof on which the cut-out is not formed is oriented toward the first board 400. Accordingly, when the first connector 1 is to be inserted or removed, the removal of the second connector 2 can be reduced.

According to this embodiment, the removal of plug at the time of work can be reduced by determining an orientation of the receptacle provided on the board.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-237432, filed Dec. 19, 2018, which is hereby incorporated by reference herein in its entirety.

What is claimed is:

1. A circuit board assembly comprising:
a first board;
a first receptacle provided on the first board;
a second board;
a second receptacle provided on the second board; and
a cable unit which includes a first plug to be inserted into the first receptacle and a second plug to be inserted into the second receptacle to electrically connect the first board and the second board to each other,
wherein the first receptacle is configured so that a force required for pulling out the first plug from the first receptacle in a direction inclined toward a first side of the first receptacle with respect to a first insertion direction in which the first plug is inserted into the first receptacle is smaller than a force required for pulling out the first plug from the first receptacle in a direction inclined toward a second side opposite to the first side with respect to the first insertion direction, and
wherein the first receptacle is provided on the first board so that the second side of the first receptacle is oriented toward the second board.

2. The circuit board assembly according to claim 1, wherein a cut-out is provided on the first side of the first receptacle so as to allow the first plug to be easily pulled out from the first receptacle.

3. The circuit board assembly according to claim 2, wherein the first receptacle is provided with an opening which is open in the first insertion direction, and the cut-out communicates to the opening.

4. The circuit board assembly according to claim 1, further comprising:
a latching portion provided to the first plug; and
a latching portion provided to the first receptacle,
wherein, when the first plug is connected to the first receptacle, the latching portion of the first plug is latched to the latching portion of the first receptacle to give an operator a click feeling.

5. The circuit board assembly according to claim 1, wherein the second receptacle is configured so that a force required for pulling out the second plug from the second receptacle in a direction inclined toward a first side of the second receptacle with respect to a second insertion direction in which the second plug is inserted into the second receptacle is smaller than a force required for pulling out the second plug from the second receptacle in a direction inclined toward a second side opposite to the first side with respect to the second insertion direction, and
wherein the second receptacle is provided on the second board so that the second side of the second receptacle is oriented toward the first board.

6. The circuit board assembly according to claim 5, wherein a cut-out is provided on the first side of the second receptacle so as to allow the second plug to be easily pulled out from the second receptacle.

7. The circuit board assembly according to claim 6, wherein the second receptacle is provided with an opening which is open in the second insertion direction, and the cut-out communicates to the opening.

8. The circuit board assembly according to claim 1, further comprising:
a latching portion provided to the second plug; and
a latching portion provided to the second receptacle,
wherein, when the second plug is connected to the second receptacle, the latching portion of the second plug is latched to the latching portion of the second receptacle to give an operator a click feeling.

9. The circuit board assembly according to claim 1, wherein the first receptacle and the second receptacle have the same structure, and
wherein the first plug and the second plug have the same structure.
